(19) United States
(12) Patent Application Publication
(10) Pub. No.: US 2021/0270636 A1
(43) Pub. Date: Sep. 2, 2021

(54) SEMICONDUCTOR DEVICE AND MEASUREMENT PROCESSING SYSTEM

(71) Applicant: LAPIS Semiconductor Co., Ltd., Yokohama-shi (JP)

(72) Inventor: Hiroji AKAHORI, Yokohama-shi (JP)

(73) Assignee: LAPIS Semiconductor Co., Ltd., Yokohama-shi (JP)

(21) Appl. No.: 17/185,914

(22) Filed: Feb. 25, 2021

(30) Foreign Application Priority Data
Feb. 28, 2020 (JP) 2020-034144

(51) Int. Cl. G01D 1/00; H03M 1/12

(52) U.S. Cl. CPC G01D 1/00; H03M 1/12

(57) ABSTRACT

An average processing section, a timer, and a control section are provided. The average processing section is configured to compute an average measurement value, this being an average value of plural observed values of each of plural measurement targets as output from a switching section that switches output between measurement values acquired from each of the plural measurement targets. The timer is configured to generate a timer signal configured by timing signals at a predetermined interval. The control section is configured to control the switching section and the average processing section so as to compute the average measurement value for each of the measurement targets according to the timer signal and according to a measurement sequence to set an order of measurement and a number of measurements for the plural measurement targets.

### CROSS-REFERENCE TO RELATED APPLICATION

This application is based on and claims priority under 35 USC 119 from Japanese Patent Application No. 2020-034144 filed on Feb. 28, 2020, the disclosure of which is incorporated by reference herein.

### TECHNICAL FIELD

The present disclosure relates to a semiconductor device and a measurement processing system.

### RELATED ART

One field within semiconductor devices concerns semiconductor devices with functionality to gather measurement values output from a sensor or the like. In semiconductor devices in this field, measurement values received from the sensor or the like may be supplied to a circuit that executes prescribed processing based on the measurement values. In such cases, precise measurement values in which external influences such as noise are suppressed may be demanded in order to execute the prescribed processing in an appropriate manner. One method for improving the precision of measurement values involves performing averaging processing on multiple measurement values. This method employs the principle that the average value of multiple sample values will approach a true value. Averaging multiple sample values may also be expected to reduce the influence of noise.

Japanese Patent Application Laid-Open (JP-A) No. 2016-095683 is an example of known literature disclosing averaging processing of measurement values. A measurement system disclosed in Japanese Patent Application Laid-Open (JP-A) No. 2016-095683 is connected to plural measuring apparatuses and a management unit so as to be capable of communicating therewith. The measuring apparatuses use sensors in a detection circuit to measure a power consumption amount. Sensor IDs used to discriminate between each of the sensors connected to the plural measuring apparatuses are acquired from the management unit, and a power consumption amount measured by a detection circuit including a sensor identified by an acquired sensor ID is transmitted to the management unit. The management unit includes a control section, and this control section uses a communication function to communicate with the measuring apparatuses. The measurement system according to Japanese Patent Application Laid-Open (JP-A) No. 2016-095683 also includes a statistic storage section that stores statistical values of average values and the like of measurement data stored in a measurement storage section as statistical data.

FIG. 6 illustrates a semiconductor device 100 according to a comparative example that includes averaging processing functionality. As illustrated in FIG. 6, the semiconductor device 100 includes a CPU 20, memory 21, an analog-to-digital conversion circuit (ADC) 14, a switching setting section 15, a switching section 16-2, and a bus 22. External switching sections 16-3, 16-4, 16-5, and circuits A1, A2 . . . An, B1, C1, and C2 are connected to the semiconductor device 100.

The CPU 20 includes functionality to employ software to compute an average value (also referred to hereafter as an “average measurement value”) from plural measurement values. The memory 21 includes functionality to store the average measurement value computed by the CPU 20. The CPU 20, the memory 21, the ADC 14, and the switching setting section 15 are capable of communicating with each other through the bus 22.

The circuits A1, A2 . . . An, B1, C1, and C2 each configure an independent measurement target, and independent measurement values for each of these circuits are output according to a unique cycle. Output signals for each of the measurement targets are analogue signals. Measurement values of the analogue signals switched by the switching sections 16-2 to 16-5 are converted to digital signals by the ADC 14 and are acquired by the CPU 20 through the bus 22.

The switching sections 16-2, 16-3, 16-4, and 16-5 (also referred to collectively as the “switching sections 16”) are, for example, configured by selectors that switch between connections to the plural measurement targets. Each of the switching sections 16 is controlled by the switching setting section 15, and measurement values are input to the ADC 14 one at a time at predetermined timings. The switching setting section 15 switches the switching sections 16-2, 16-3, 16-4, and 16-5 based on instructions from the CPU so as to control the measurement target to be input to the ADC 14. Note that although the switching section 16-2 is built into the semiconductor device 100 whereas the switching sections 16-3 to 16-5 are provided externally to the semiconductor device 100, each of the switching sections 16 has the same functionality.

In the semiconductor device 100, the above-described procedure for measuring the plural measurement targets while switching the input to the ADC 14 is performed by software. Average measurement values are output and measurements are taken for the plural sensors on a predetermined cycle. Generally, in cases in which routine fluctuations (fluctuations not including external interference) in measurement values output from the sensors are not especially large, and in cases in which further improvements in precision are not demanded for the measurement targets, the influence of noise can be reduced and the precision of the average measurement values can be raised by increasing the number of measurements and performing averaging processing for a greater number of parameters.

However, two issues arise when attempting to increase the number of measurement value measurements and improve the precision of the average measurement values in the semiconductor device 100 according to the comparative example.

A first issue is that the CPU, the memory, the bus, and so on are occupied with the measurement processing by the software, leaving the CPU unavailable to execute other processing during the measurement processing. Semiconductor devices installed with such a CPU and memory are typically ordinary microcomputers, and when considered as a system with communication functionality and the like, there is often other functionality that has a higher priority than the measurement processing. Accordingly, cases may arise in which there is no alternative but to halt the measurement processing when high priority processing arises. Although methods to allocate processing time in advance such that measurement processing is not halted are conceivable, such methods reduce the amount of time during which measurement is possible. As a result it is not possible to achieve the hoped-for number of measurements.

A second issue is that when measurements are performed by software, the time required for a single measurement takes plural time divisions on a hardware actuation clock. The time required for measurement is rate-limited by software processing and, for example, measurements are not able to be taken at each interval of the ADC sampling frequency. Moreover, although the averaging processing is also executed by software, measurement (measurement data acquisition) is not able to be performed during such averaging processing.

As described above, the number of measurements is generally limited when measurement processing is performed by software, and so it is often not possible to achieve a sufficient number of measurements to produce an averaging effect for a multiple population. Although steps may be considered to boost measurement circuit performance in order to make up for the shortfall in the number of measurements, such an approach entails issues of increased cost.

### SUMMARY

In consideration of the above circumstances, an object of the present invention is to provide a semiconductor device and a measurement processing system provided with a configuration that performs processing to average multiple measurement values in order to compute an average measurement value, the semiconductor device and the measurement processing system being capable of acquiring a more accurate average measurement value in a shorter time than in cases in which software processing is employed. [0015] In order to resolve these issues, a semiconductor device according to an exemplary embodiment of the present invention includes an average processing section, a timer, and a control section. The average processing section is configured to compute an average measurement value, this being an average value of plural observed values of each of plural measurement targets as output from a switching section that switches output between measurement values acquired from each of the plural measurement targets. The timer is configured to generate a timer signal configured by timing signals at a predetermined interval. The control section is configured to control the switching section and the average processing section so as to compute the average measurement value for each of the measurement targets according to the timer signal and according to a measurement sequence to set an order of measurement and a number of measurements for the plural measurement targets.

In order to resolve these issues, a measurement processing system according to an exemplary embodiment of the present invention includes a switching section configured to switch output between measurement values acquired from each of plural measurement targets, and a microcomputer. The microcomputer includes an average processing section, a timer, a control section, and a CPU. The average processing section is configured to compute an average measurement value, this being an average value of plural observed values of each of the plural measurement targets as output from the switching section. The timer is configured to generate a timer signal configured by timing signals at a predetermined interval. The control section is configured to control the switching section and the average processing section so as to compute the average measurement value for each of the measurement targets according to the timer signal and according to a measurement sequence to set an order of measurement and a number of measurements for the plural measurement targets. The CPU is configured to use communication functionality to supply the average measurement values computed by the average processing section for the plural measurement targets to external circuits corresponding to the respective measurement targets. [0017] Exemplary embodiments of the present invention exhibit an advantageous effect of providing a semiconductor device and a measurement processing system provided with a configuration that performs processing to average multiple measurement values in order to compute an average measurement value, the semiconductor device and the measurement processing system being capable of acquiring a more accurate average measurement value in a shorter time than in cases in which software processing is employed.

### BRIEF DESCRIPTION OF DRAWINGS

FIG. 1A is a block diagram illustrating an example of configuration of a semiconductor device according to a first exemplary embodiment;

FIG. 1B is a block diagram illustrating an example of configuration of an average processing section according to the first exemplary embodiment;

FIG. 2A is a timing chart illustrating a relationship between timer signals TIM1 and TIM2 during an averaging processing routine i of a semiconductor device according to the first exemplary embodiment;

FIG. 2B is a timing chart illustrating an arrangement of switching timings and measurement timings during a measurement sequence of a semiconductor device according to the first exemplary embodiment;

FIG. 2C is a schematic diagram illustrating an example of a measurement sequence of a semiconductor according to the first exemplary embodiment;

FIG. 3 is a block diagram illustrating an example of configuration of a semiconductor device and a measurement processing system according to a second exemplary embodiment;

FIG. 4 is a block diagram illustrating an example of configuration of a semiconductor device and a measurement processing system according to a third exemplary embodiment;

FIG. 5A is a block diagram illustrating an example of configuration of a semiconductor and a measurement processing system according to a fourth exemplary embodiment;

FIG. 5B is a timing chart illustrating an arrangement of switching timings and measurement timings during a measurement sequence of a semiconductor device according to the fourth exemplary embodiment; and

FIG. 6 is a block diagram illustrating configuration of a semiconductor device according to a comparative example.

### DETAILED DESCRIPTION

Detailed explanation follows regarding exemplary embodiments of the present disclosure, with reference to the drawings.

### First Exemplary Embodiment

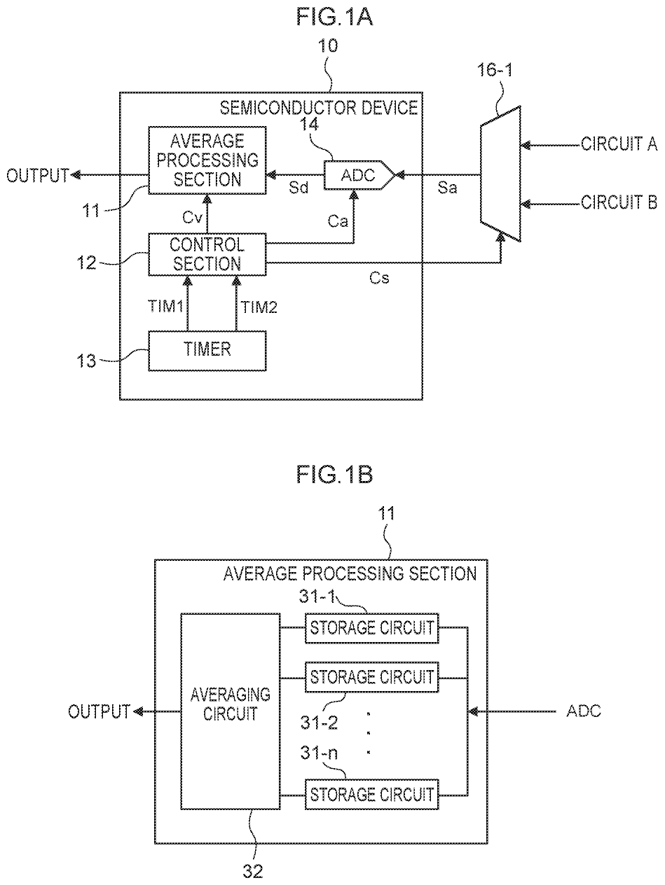

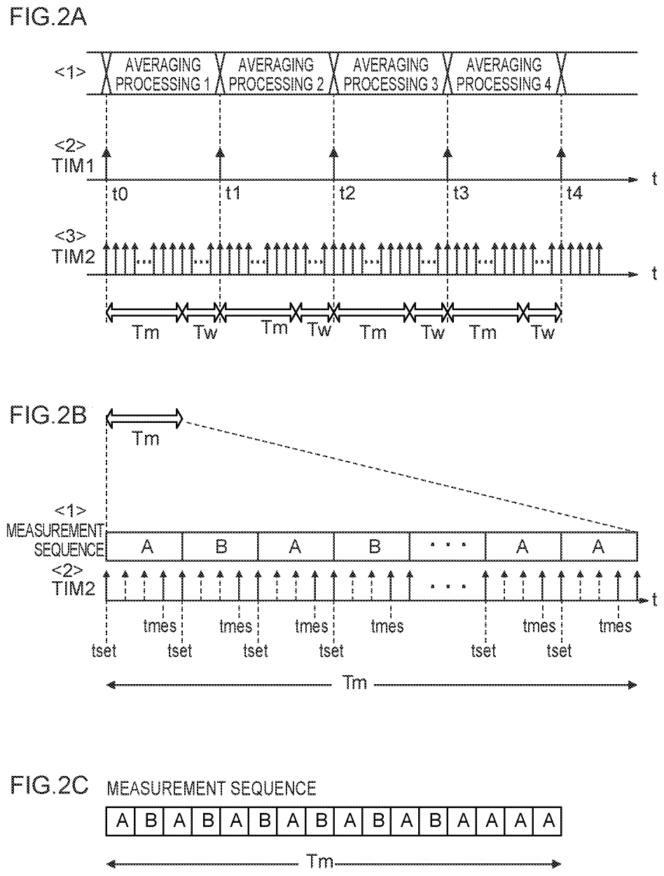

Explanation follows regarding a semiconductor device 10 according to a first exemplary embodiment, with reference to FIG. 1A, FIG. 2A, FIG. 2B, and FIG. 2C. An example is given in which the semiconductor device 10 measures two measurement targets, namely a circuit A and a circuit B. Note that measurement values for the measurement targets in the present exemplary embodiment are not limited to circuitry characteristics (such as voltage or current), and application may be made to other general sensor outputs such as temperature or pressure.

Explanation follows regarding configuration of the semiconductor device 10, with reference to FIG. 1A and FIG. 1B. As illustrated in FIG. 1A, the semiconductor device 10 includes an average processing section 11, a control section 12, a timer 13, and an ADC 14. The semiconductor device 10 also includes an external switching section 16-1. The switching section 16-1 is, for example, configured by a selector or a switch, and switches the measurement target between the circuit A and the circuit B.

The ADC 14 converts an analogue measurement value Sa sent from the switching section 16-1 for either the circuit A or the circuit B into a digital measurement value Sd, and sends the digital measurement value Sd to the average processing section 11.

The average processing section 11 computes an average value for the measurement target from plural measurement values sequentially input from the ADC 14, and outputs an average measurement value through an output section (not illustrated in the drawings). Note that in the semiconductor device according to the present disclosure, averaging processing may be executed on digital measurement values Sd input to the average processing section 11 directly instead of through the ADC 14. In such cases, the digital measurement values Sd are, for example, output from the measurement targets. The average processing section may be implemented by either hardware (circuitry) or software (i.e. using a processing circuit to execute program commands held on a storage medium).

The control section 12 controls an actuation timing of the average processing section 11, and controls a switching timing of the switching section 16-1 coordinated with the actuation timing. In the semiconductor device 100 according to the comparative example described previously, it is necessary for the CPU 20 to execute consecutive switching according to software. However, in the semiconductor device 10, the control section 12 executes switching by coordinating with the actuation of the ADC 14, and by controlling the switching section 16-1 according to a timing (the switching timing tset indicated by <2> in FIG. 2B) that considers the time required for each switching (for example the time taken for an internal state of an analogue circuit that is the measurement target to settle).

Namely, the switching timing of the switching section 16-1 is set by software incorporated in the control section 12 in consideration of a settling timing when switching between the respective measurement targets, or in consideration of the switching characteristics of the switching section 16-1. Note that although explanation is given in which the switching control of the switching section 16-1 is given as an example of control by the control section 12 in the present exemplary embodiment, the control may be of an external circuit that does not require switching. The control section 12 according to the present exemplary embodiment controls the average processing section 11 with a control signal Cv according to two timer signals TIM1, TIM2 from the timer 13, controls the ADC 14 with a control signal Ca, and controls the switching section 16-1 with a control signal Cs. The control section may be implemented by either hardware (circuitry) or software (i.e. using a processing circuit to execute program commands held on a storage medium).

The timer 13 generates timer signals configured by timing signals used to generate control signals for the control section 12 to control various locations. As described above, the timer signals include two types of timer signals, namely the timer signals TIM1, TIM2. The timer signals TIM1, TIM2 are synchronized with each other, and a timing interval of the timer signal TIM2 is shorter than a timing interval of the timer signal TIM1. Once the timer 13 has been started, the timer signals TIM1, TIM2 continue to be output even if there is no subsequent software control or the like. Note that the timer signals do not necessary have to be split into the two timer signals configured by TIM1 and TIM2, and a single timer signal may be employed. In such cases, the timer signal TIM2 is employed as the timer signal.

Explanation follows regarding configuration of the average processing section 11, with reference to FIG. 1B. As illustrated in FIG. 1B, the average processing section 11 includes an averaging circuit 32, and plural storage circuits 31-1, 31-2, . . . 31-n (also referred to collectively as the storage circuits 31). The storage circuits 31 are storage circuits (buffer memory) that temporarily store measurement values sent from the ADC 14, with one of the storage circuits 31 being allocated to each of the plural measurement targets. Since there are two measurement targets in the present exemplary embodiment, two storage circuits 31 out of the plural storage circuits 31 (n storage circuits 31 in the example illustrated in FIG. 1B) are employed (alternatively, just two storage circuits 31 are included). Memory is a specific example of the storage circuits 31; however, integrator circuits may be employed instead of memory.

The averaging circuit 32 executes averaging processing on the measurement values sent from the corresponding storage circuits 31 for each of the measurement targets in order to compute and output an average measurement value.

Next, detailed explanation follows regarding the averaging processing executed in the semiconductor device 10, with reference to FIG. 2A, FIG. 2B, and FIG. 2C. FIG. 2A illustrates the relationship between the timer signals TIM1, TIM2 during the averaging processing. FIG. 2B illustrates a relationship between a measurement timing and switching controlled according to the timer signal TIM2, and FIG. 2C illustrates an example of a measurement sequence.

As indicated by <1> in FIG. 2A, the averaging processing according to the present exemplary embodiment is made up of consecutive averaging processing routines 1, 2, 3, 4, . . . (also referred to hereafter as the “averaging processing routines i”) at timing intervals designated by the timer signal TIM1. At each timing designated by the timer signal TIM1, namely at each of the time increments t0, t1, t2, t3, t4, . . . illustrated by <2> in FIG. 2A, the average processing section 11 outputs average measurement values for the respective measurement targets.

<3> in FIG. 2A illustrates processing performed during each of the averaging processing routines i. As illustrated by <3> in FIG. 2A, each of the averaging processing routines i is configured of a measurement timeslot Tm and a reserve timeslot Tw. The measurement timeslot Tm is a timeslot for executing measurement of the plural measurement targets (acquiring digital measurement data from the ADC 14). The reserve timeslot Tw is a timeslot between the measurement timeslots Tm, during which no processing is executed. Note that the reserve timeslot Tw is not essential, and may be omitted, for example in cases in which there is a desire to speed up the averaging processing.

Note that in the semiconductor device 10 according to the present exemplary embodiment, the processing in the respective averaging processing routines i is executed according to a measurement sequence. The measurement sequence is set out in a table used to set the order of measurement and the number of measurements for the respective measurement targets, and is created by the control section 12 in the present exemplary embodiment. FIG. 2C illustrates an example of the measurement sequence. The duration of the measurement sequence is set to the measurement timeslot Tm. FIG. 2C illustrates an example in which the circuit A is measured ten times and the circuit B is measured six times. The order of measurement is set such that the circuit A and the circuit B are measured alternately where possible. This is to suppress fluctuations in the measurement values of the respective measurement targets during the measurement timing as far as possible.

FIG. 2B illustrates switching and measurement timings controlled according to the timer signal TIM2. <1> in FIG. 2B illustrates the measurement sequence illustrated in FIG. 2C. In the present exemplary embodiment, a switching timing tset and a measurement timing tmes are set for each of the measurement targets (circuit A and circuit B) included in the measurement sequence. The switching timing tset is a switching timing of the switching section 16-1 sent through the control signal Cs. The measurement timing tmes is sent using the control signals Cv, Ca, and is a timing when the average processing section 11 acquires the measurement value from the ADC 14. As illustrated by <2> in FIG. 2B, a time lag (a time lag corresponding to two pulses of the timer signal TIM2 in the example illustrated in <2> in FIG. 2B) is provided between the switching timing tset and the measurement timing tmes. The time lag is set in consideration of the time taken for stabilization after the switching section 16-1 has received the switching timing tset, the time taken for the measurement values of the measurement targets to stabilize, and so on. Although the time lag set between the switching timing tset and the measurement timing tmes has a fixed value in the present exemplary embodiment, the time lag value may be set to any desired value by the software employed by the control section 12.

As described in detail above, in the semiconductor device 10 according to the present exemplary embodiment, the respective processing of the switching section 16, the ADC 14, and the average processing section 11 is executed by independent hardware processing based on the preset timer signals and according to the preset measurement sequence. When this is performed, the measurement sequence may be set by the control section 12 using software, and the order of measurement, the number of measurements, and the like of the measurement targets may be set flexibly. Moreover, the timer signals are independently generated by the timer 13, and constant processing timings continue to be supplied unless, for example, a stop signal is output from the control section 12. The processing timings are set such that processing is executed in the minimum possible time, in consideration of the time required for the respective processing by the switching sections 16, the ADC 14, the average processing section 11, and the control section 12. The timing intervals and the like of the timer signals from the timer 13 may also be set flexibly using software.

In the semiconductor device 10 according to the present exemplary embodiment, a segment for executing the averaging processing routine i is set, and the timer signal TIM1 designating the average measurement value output timings, and the two timer signals that respectively designate the switching timing tset and the measurement timing tmes during the measurement sequence are employed. This simplifies the control of the respective sections of the switching section 16-1, the ADC 14, and the average processing section 11 by the control section 12, thereby lightening the burden on the control section 12.

### Second Exemplary Embodiment

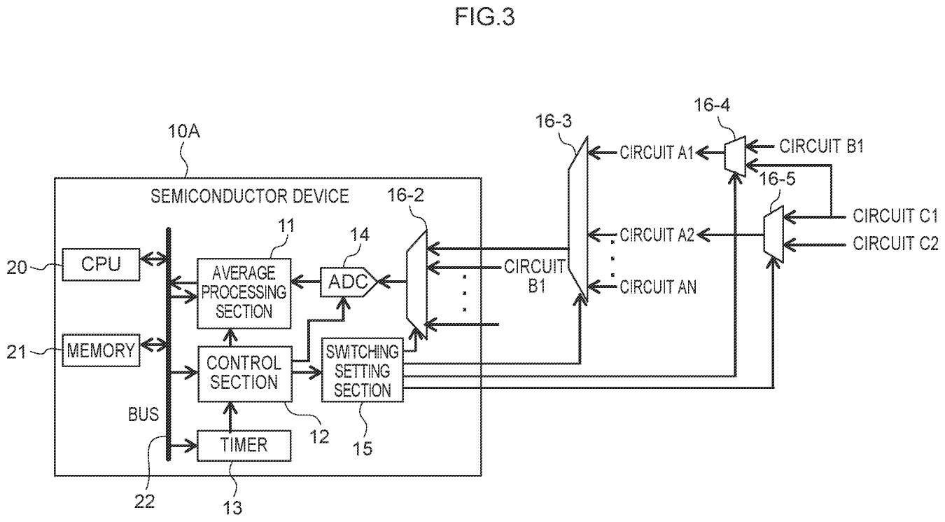

Explanation follows regarding a semiconductor device and a measurement processing system according to a second exemplary embodiment, with reference to FIG. 3. As illustrated in FIG. 3, the measurement processing system according to the present exemplary embodiment is configured including a semiconductor device 10A and switching sections 16-3, 16-4, 16-5. Moreover, as illustrated in FIG. 3, the semiconductor device 10A is further configured including an average processing section 11, a control section 12, a timer 13, an ADC 14, a switching setting section 15, a switching section 16-2, a CPU 20, and memory 21. The switching sections 16-3, 16-4, 16-5 are provided externally to the semiconductor device 10A. Circuits A1, A2, . . . An, a circuit B1, and circuits C1, C2 configure measurement targets of the semiconductor device 10A.

Functionality of the average processing section 11, the control section 12, the timer 13, and the ADC 14 is similar to that of the first exemplary embodiment, and so detailed explanation thereof is omitted. The semiconductor device 10A according to the present exemplary embodiment is provided with the switching setting section 15, the switching section 16-2, the CPU 20, the memory 21, and a bus 22 in addition to the configuration of the semiconductor device 10.

The switching section 16-2 is a switching section provided in close proximity to the input of the ADC 14, and is provided as standard in the semiconductor device 10A. The switching section may thus be provided either externally or internally. In the semiconductor device 10A, since there are (n+3) measurement targets and these measurement targets are controlled by four switching sections, switching is more complex. The present exemplary embodiment is therefore provided with the dedicated switching setting section 15 to control switching of the respective switching sections. The switching setting section 15 switches one at a time between the measurement values input to the ADC 14 for each of the measurement targets based on instructions from the control section 12.

In the semiconductor device 10A according to the present exemplary embodiment, the control section 12, the average processing section 11, the ADC 14, and the switching setting section 15 are actuated according to the timer signals TIM1, TIM2 generated by the timer 13, and the averaging processing routines i are executed according to the measurement sequence set by the control section 12.

The CPU 20 uses, for example, a communication function (not illustrated in the drawings) to supply the respective average measurement values received from the average processing section 11 via the bus 22 to an external functional section that executes predetermined processing using the average measurement values. The memory 21 for example stores the average measurement values computed by the average processing section 11.

Similarly to the semiconductor device 10, the semiconductor device 10A also executes averaging processing on a stipulated number of samples of the measurement values sent from the ADC 14 for each of the measurement targets. In the averaging processing, the number of measurements and the order of measurement are set individually for each of the measurement targets based on the measurement sequence.

For example, in cases in which averaging processing is performed when measurement values for the circuit A1 and the circuit A2 (the notation “circuit A1” is abbreviated to “A1” and so on hereafter) illustrated in FIG. 3 are measured alternately, the measurement order and number for the measurement targets is for example designated as the measurement sequence <A1, A2, A1, A2, . . . , A1, A2>. In such cases, a repetition cycle of the measurement sequence is (A1, A2). The respective measurement values for A1, A2 are alternately acquired in sequence by the ADC 14, allocated to storage circuits 31 (see FIG. 1B), and average measurement values are computed individually. Although the above measurement sequence is an example in which A1 and A2 are arranged alternately, there is no limitation to such an arrangement, and A1 and A2 may both be arranged consecutively. Moreover, the number of measurement targets is not limited to two, and any desired number thereof may be set, with the required number of switching sections 16 being provided according to the number of measurement targets. Moreover, there is no need for a repetition unit of (A1, A2), and a repetition unit with different numbers may be applied according to the number of measurements taken for each of the A1 and A2.

Moreover, the present exemplary embodiment may also be applied to cases in which the measurement values for a given circuit are controlled using output from another circuit. Take, for example, a case in which it is desirable to change measurement values of a given circuit using a value as a parameter. In such cases, the measurement values of the given circuit are changed based on the other circuit. The changing of measurement values referred to here also includes, for example, cases in which the gain of a measurement target circuit is changed. Of the circuits illustrated in FIG. 3, for example, for A1 a measurement value is changed by the output of the switching section 16-4, i.e. using either B1 or C1, these being, and for A2 a measurement value is changed by the output of the switching section 16-5, i.e. using either C1 or C2. In such cases, measuring can be performed based on the settings of the switching section 16-4 or the switching section 16-5.

Note that when a value for A1 is changed using B1, for example, A1 is expressed as A1 (B1). In such cases, the measurement sequence may, for example, be set to <A1 (B1), A2, A1 (C1), A2, A1 (B1), A2, A1 (C1), A2, . . . , A1 (B1), A2, A1 (C1), A2>. The repetition cycle of the measurement sequence in this case is (A1 (B1), A2, A1 (C1), A2). This enables number of samples to be designated for A1 (B1), A2, A1 (C1) and the respective average measurement values thereof to be acquired. Note that as previously described, the cycle (A1 (B1), A2, A1 (C1), A2) does not necessary have to be repeated.

More specifically, A1 (B1), A2, A1 (C1) may each be measured consecutively, and average measurement values computed using a different number of samples for each. As an example, measurement conditions for A1 (B1), A2, A1 (C1), A2 are set as below.
A1 (B1): number of consecutive measurements=2, number of samples=4
A1 (C1): number of consecutive measurements=3, number of samples=10
A2: number of consecutive measurements=1, number of samples=6

In this case, the measurement sequence is as follows.
<A1 (B1), A1 (B1), A1 (C1), A1 (C1), A1 (C1), A2, A1 (B1), A1 (B1), A1 (C1), A1 (C1), A1 (C1), A2, A1 (C1), A1 (C1), A1 (C1), A2, A1 (C1), A2, A2, A2>

The above measurement sequence is set using software by the control section 12.

As described in detail above, the semiconductor device 10A according to the present exemplary embodiment corresponds to a semiconductor device and a measurement processing system configured such that switching sections 16 are provided not only externally but also internally, and average measurement values are computed by performing averaging processing on multiple measurement values. This enables more accurate average measurement values to be acquired in a shorter time than in cases in which software processing is employed. Moreover, in the semiconductor device 10A according to the present exemplary embodiment, the averaging processing is executed by hardware independently of the CPU 20, thereby lightening the burden on software processing by the CPU 20 in comparison to the semiconductor device 100 according to the comparative example previously described. The CPU 20 is thus able to take on other software processing. Alternatively, as a result of lightening the burden, the operating speed of the CPU 20 may be reduced, and the memory capacity provided for programs and data may also be reduced.

### Third Exemplary Embodiment

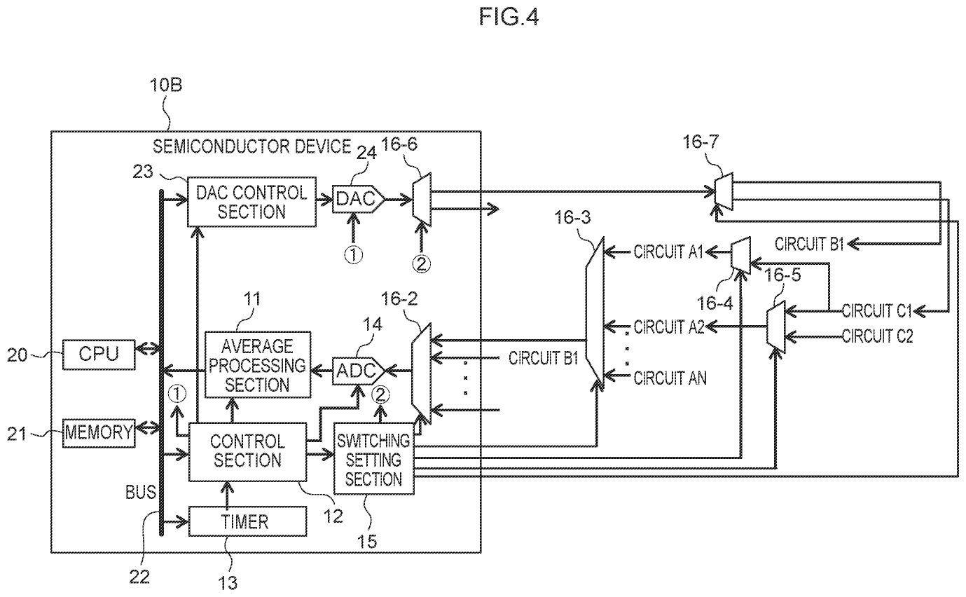

Explanation follows regarding a semiconductor device and measurement processing system according to a third exemplary embodiment, with reference to FIG. 4. As illustrated in FIG. 4, a measurement processing system according to the present exemplary embodiment is configured including a semiconductor device 10B and switching sections 16-3, 16-4, 16-5, 16-7. As illustrated in FIG. 4, the semiconductor device 10B further includes a digital-to-analogue conversion circuit (DAC) control section 23, a DAC 24, and a switching section 16-6 in addition to the configuration of the semiconductor device 10A illustrated in FIG. 3. Accordingly, configuration similar to that of the semiconductor device 10A is allocated the same reference numerals, and detailed explanation thereof is omitted. The external switching section 16-7 is also connected to the semiconductor device 10B. Note that the DAC control section 23, the DAC 24, and the switching sections 16-6, 16-7 are examples of a “change setting section” according to the present disclosure.

The DAC control section 23, the DAC 24, and the switching sections 16-6, 16-7 include functionality to change the measurement values of external circuits (measurement targets) with analogue signals. Namely, the semiconductor device 10B includes configuration to control external circuits using internal circuits. For example, in FIG. 4, B1 and C1 can be controlled by output from the semiconductor device 10B by switching the switching section 16-7.

Cases arise in which it becomes necessary to change the value of a signal supplied to a circuit configuring a measurement target in response to a measurement result. Cases also arise in which it is desirable to change the value of a signal supplied to a circuit in accordance with the type of circuit measurement. Since the semiconductor device 10B according to the present exemplary embodiment includes the DAC control section 23, the DAC 24, and the switching section 16-6, such functionality can be provided as standard.

The DAC control section 23 includes functionality to control the DAC 24 based on instructions from the control section 12. The DAC control section 23 generates digital signals to control external circuits (B1, C1 in the example in FIG. 4) based on instructions from the control section 12. The DAC control section 23 may be configured to acquire digital signals used to control the external circuits from outside the semiconductor device 10B.

The DAC 24 converts digital signals received from the DAC control section 23 into analogue signals. The switching sections 16-6, 16-7 switch supply of analogue signals from the DAC 24 between the circuits (B1, C1).

As illustrated in FIG. 4, the DAC control section 23 and the DAC 24 are input with control signals from the control section 12, and control is performed by the DAC control section 23. Processing of the DAC control section 23, the DAC 24, and the switching sections 16-6, 16-7 is also executed based on timing signals supplied by the timer signals TIM1, TIM2 illustrated in FIG. 1A. The order and number of analogue signals supplied from the DAC 24 is incorporated and set in the measurement sequence illustrated in FIG. 2C.

### Fourth Exemplary Embodiment

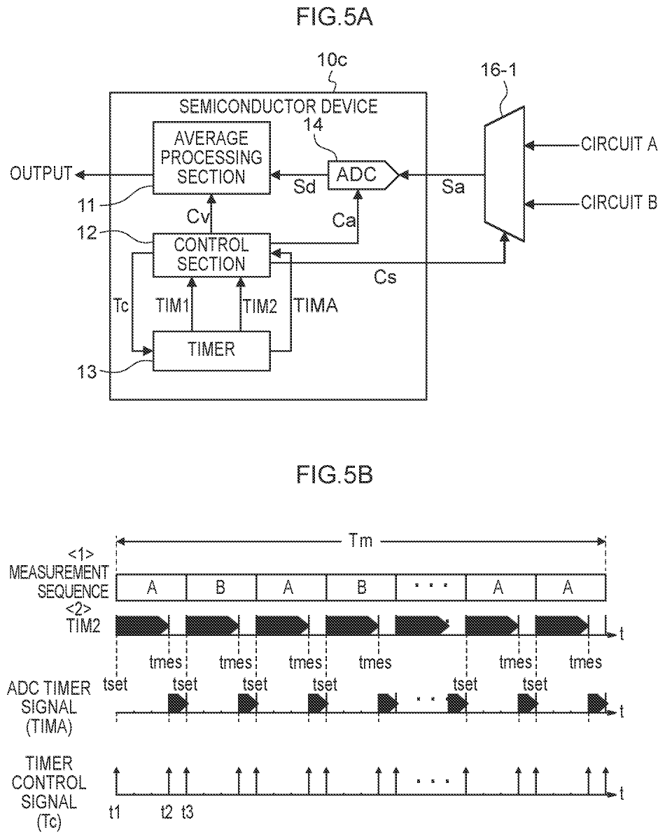

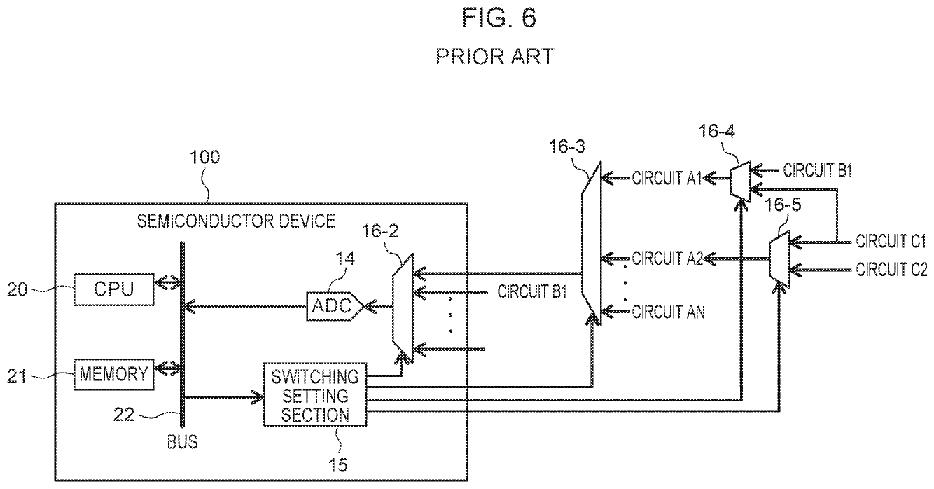

Explanation follows regarding a semiconductor device and measurement processing system according to a fourth exemplary embodiment, with reference to FIG. 5A and FIG. 5B. As illustrated in FIG. 5A, a measurement processing system according to the present exemplary embodiment is configured including a semiconductor device 10C and a switching section 16-1. Moreover, as illustrated in FIG. 5A, the semiconductor device 10C includes an ADC timer signal TIMA input to the control section 12 from the timer 13, and a timer control signal Tc input to the timer 13 from the control section 12 in addition to the configuration of the semiconductor device 10 illustrated in FIG. 1A. Accordingly, configuration similar to that of the semiconductor device 10 is allocated the same reference numerals, and detailed explanation thereof is omitted.

The ADC timer signal TIMA according to the present exemplary embodiment is a signal to set a timeslot from the measurement timing tmes to the switching timing tset. The timer control signal Tc is a signal to generate a start trigger for the timers that generate the timer signal TIM2 and the ADC timer signal TIMA.

In the first exemplary embodiment described above, the time lag configuring the timeslot from the switching timing tset to the measurement timing tmes is configured by a fixed value. In the first exemplary embodiment, this time lag is set in consideration of the time taken for stabilization after the switching section 16-1 has received the switching timing tset, and in consideration of the time taken for the measurement values of the measurement targets to stabilize for each of the circuit A and the circuit B configuring the measurement targets. However, there are also cases in which there is demand to set this time lag more flexibly according to the characteristics of the measurement processing system and the like. The present exemplary embodiment is a configuration capable of accommodating such a system.

More detailed explanation follows regarding operation of the semiconductor device 10C, with reference to FIG. 5B. <1> in FIG. 5B is the same as the measurement sequence illustrated in FIG. 2C, and has a cycle corresponding to the measurement timeslot Tm. A time lag from the switching timing tset to the measurement timing tmes is set by the timer signal TIM2, and the timeslot from the measurement timing tmes to the switching timing tset is set by the ADC timer signal TIMA. Note that in the semiconductor device 10C, the timers (not illustrated in the drawings) that generate the timer signal TIM2 and the ADC timer signal TIMA are configured by timers that turn off automatically after remaining ON (after measuring time) for a predetermined time following input of a trigger signal to start the timer. Note that although a time measurement duration of the timer signal TIM2 and a time measurement duration of the ADC timer signal TIMA are different to each other in the present exemplary embodiment, these may be the same as each other.

The timer control signal Tc includes functionality as a signal to generate a start trigger to start the timers that generate the timer signal TIM2 and the ADC timer signal TIMA. Namely, on the first measurement of the circuit A illustrated in <1> in FIG. 5B, the timer control signal Tc generates one pulse at a time at each of the time increments t1, t2, t3. The pulse at the time increment t1 is a start trigger that starts the timer of the timer signal TIM2 to designate the switching timing tset, and the timer of the timer signal TIM2 turns itself OFF after the predetermined time measurement duration has elapsed. When this occurs, the timer signal TIM2 is transmitted to the control section 12. The timing at which the timer of the timer signal TIM2 turns itself OFF configures the measurement timing tmes when measurement of the circuit A is executed.

The control section 12 detects that the timer of the timer signal TIM2 is OFF, and transmits this detection to the timer 13. Based on this detection signal, the timer 13 emits a start trigger that starts the timer of the ADC timer signal at the time increment t2. The pulse at the time increment t2 configures a start trigger that turns the timer of the ADC timer signal TIMA OFF after the predetermined measurement duration. When this occurs, the ADC timer signal TIMA is transmitted to the control section 12. The time measurement duration of the timer of the ADC timer signal TIMA designates a timeslot from the measurement timing tmes to the switching timing tset. The control section 12 detects that the timer of the ADC timer signal TIMA is OFF, and transmits this detection to the timer 13. This detection signal becomes the pulse of the timer control signal Tc at the time increment t3, and this pulse serves as a start trigger to start the timer signal TIM2. Subsequent measurement of the circuit B is executed by a similar operation.

Note that although the timeslot from the switching timing tset to the measurement timing tmes for circuit B is the same as the timeslot from the switching timing tset to the measurement timing tmes for the circuit A in the present exemplary embodiment, the circuit B may have a different timeslot to the timeslot of the circuit A. In such cases, setting of the timer that generates the timer signal TIM2 based on the timer control signal Tc may be changed to change the time measurement duration of the timer signal TIM2, or another timer (not illustrated in the drawings) may be provided to generate a timer signal for a different time measurement duration of the timer signal TIM2, such that this timer is started. Similar also applies in the case of the timeslot from the measurement timing tmes to the switching timing tset for the circuit B.

Moreover, the present exemplary embodiment may be applied in cases in which plural switching sections are present, as in the case of the second exemplary embodiment. In such cases, timers that set the timeslot from the switching timing tset to the measurement timing tmes and timers that set the timeslot from the measurement timing tmes to the switching timing tset may be further provided corresponding to the number switching sections and the number of circuits configuring measurement targets.

As described above, the semiconductor device and measurement processing system according to the present exemplary embodiment exhibit the advantageous effect of enabling a timeslot from the switching timing tset to the measurement timing tmes to be set flexibly according to the measurement targets and the like.

What is claimed is:

1. A semiconductor device, comprising:
an average processing section configured to compute an average measurement value that is an average value of a plurality of observed values of each of a plurality of measurement targets that are output from a switching section that switches output between measurement values acquired from each of the plurality of measurement targets;
a timer configured to generate a timer signal configured by timing signals at a predetermined interval; and
a control section configured to control the switching section and the average processing section so as to compute the average measurement value for each of the measurement targets, in accordance with the timer signal and in accordance with a measurement sequence configured to set an order of measurement and a number of measurements for the plurality of measurement targets.

2. The semiconductor device of claim 1, wherein the control section is configured to control the switching section and the average processing section so as to execute the measurement sequence repeatedly, and to control the average processing section so as to output a plurality of the average measurement values for each cycle of the measurement sequence.

3. The semiconductor device of claim 1, wherein:
a measurement value acquired by the switching section is an analogue measurement value;
the average processing section is configured to compute the average measurement value for a plurality of digital measurement values;
the semiconductor device further comprises an analog-to-digital conversion section disposed between the switching section and the average processing section; and
the control section is further configured to control the analog-to-digital conversion section in accordance with the timer signal.

4. The semiconductor device of claim 1, wherein;
the timer is configured to generate a first timer signal configured by a predetermined timing signal, and to generate a second timer signal configured by a timing signal that is faster than the first timer signal; and
the control section is configured to use the first timer signal to set a segment for the measurement sequence, and to use the second timer signal to set a switching timing in the measurement sequence for the switching section and a measurement timing in the measurement sequence for the plurality of measurement targets.

5. The semiconductor device of claim 1, further comprising a change setting section configured to change a measurement value output from at least one of the plurality of measurement targets.

6. The semiconductor device of claim 1, further comprising a processor provided with external communication functionality, wherein:
the processor is configured to use the communication functionality to supply average measurement values, computed by the average processing section for a plurality of measurement targets, to external circuits corresponding to the respective measurement targets.

7. The semiconductor device of claim 2, wherein:
a measurement value acquired by the switching section is an analogue measurement value;
the average processing section is configured to compute the average measurement value for a plurality of digital measurement values;
the semiconductor device further comprises an analog-to-digital conversion section disposed between the switching section and the average processing section; and
the control section is further configured to control the analog-to-digital conversion section in accordance with the timer signal.

8. The semiconductor device of claim 2, wherein:
the timer is configured to generate a first timer signal configured by a predetermined timing signal, and to generate a second timer signal configured by a timing signal that is faster than the first timer signal; and
the control section is configured to use the first timer signal to set a segment for the measurement sequence, and to use the second timer signal to set a switching timing in the measurement sequence for the switching section and a measurement timing in the measurement sequence for the plurality of measurement targets.

9. The semiconductor device of claim 2, further comprising a change setting section configured to change a measurement value output from at least one of the plurality of measurement targets.

10. The semiconductor device of claim 2, further comprising a processor provided with external communication functionality, wherein:
the processor is configured to use the communication functionality to supply average measurement values, computed by the average processing section for a plurality of measurement targets, to external circuits corresponding to the respective measurement targets.

11. The semiconductor device of claim 3, wherein:
the timer is configured to generate a first timer signal configured by a predetermined timing signal, and to generate a second timer signal configured by a timing signal that is faster than the first timer signal; and
the control section is configured to use the first timer signal to set a segment for the measurement sequence, and to use the second timer signal to set a switching timing in the measurement sequence for the switching section and a measurement timing in the measurement sequence for the plurality of measurement targets.

12. The semiconductor device of claim 3, further comprising a change setting section configured to change a measurement value output from at least one of the plurality of measurement targets.

13. The semiconductor device of claim 3, further comprising a processor provided with external communication functionality, wherein:
the processor is configured to use the communication functionality to supply average measurement values computed by the average processing section for a plurality of measurement targets to external circuits corresponding to the respective measurement targets.

14. The semiconductor device of claim 4, further comprising a change setting section configured to change a measurement value output from at least one of the plurality of measurement targets.

15. The semiconductor device of claim 4, further comprising a processor provided with external communication functionality, wherein:
the processor is configured to use the communication functionality to supply average measurement values computed by the average processing section for a plurality of measurement targets to external circuits corresponding to the respective measurement targets.

16. The semiconductor device of claim 7, wherein:
the timer is configured to generate a first timer signal configured by a predetermined timing signal, and to generate a second timer signal configured by a timing signal that is faster than the first timer signal; and
the control section is configured to use the first timer signal to set a segment for the measurement sequence, and to use the second timer signal to set a switching timing in the measurement sequence for the switching section and a measurement timing in the measurement sequence for the plurality of measurement targets.

17. The semiconductor device of claim 7, further comprising a change setting section configured to change a measurement value output from at least one of the plurality of measurement targets.

18. The semiconductor device of claim 7, further comprising a processor provided with external communication functionality, wherein:
the processor is configured to use the communication functionality to supply average measurement values computed by the average processing section for a plurality of measurement targets to external circuits corresponding to the respective measurement targets.

19. A measurement processing system, comprising:
a switching section configured to switch output between measurement values acquired from each of a plurality of measurement targets; and
a microcomputer including:
an average processing section configured to compute an average measurement value that is an average value of a plurality of observed values of each of the plurality of measurement targets, which are output from the switching section,
a timer configured to generate a timer signal configured by timing signals at a predetermined interval,
a control section configured to control the switching section and the average processing section so as to compute the average measurement value for each of the measurement targets, in accordance with the timer signal and in accordance with a measurement sequence to set an order of measurement and a number of measurements for the plurality of measurement targets, and
a processor configured to use communication functionality to supply the average measurement values computed by the average processing section for the plurality of measurement targets to external circuits corresponding to the respective measurement targets.
